(19) United States
(12) Patent Application Publication
(10) Pub. No.: US 2003/0054669 A1
(43) Pub. Date: Mar. 20, 2003

(54) Amorphous metal oxide gate dielectric structure and method thereof

(76) Inventors: Prasad V. Alluri, Round Rock, TX (US); Robert L. Hance, Austin, TX (US); Bich-Yen Nguyen, Austin, TX (US); Christopher C. Hobbs, Austin, TX (US); Philip J. Tobin, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/286,618

(22) Filed: Nov. 1, 2002

Related U.S. Application Data
(62) Division of application No. 09/567,276, filed on May 9, 2000.

(51) Int. Cl. H01L 29/76; H01L 31/062; H01L 21/31

(52) U.S. Cl. 438/785; 438/778; 438/591; 257/411

(57) ABSTRACT

In accordance with a specific embodiment of the present invention, a method of forming a gate dielectric is disclosed. A semiconductor wafer is placed in a deposition chamber. The semiconductor wafer is heated and a precursor gas is flowed into the chamber. In one embodiment, the precursor comprises a moiety of silicon, oxygen, and a transition metal. In another embodiment, the moiety includes a group 2 metal.

### FIELD OF THE INVENTION

The present invention relates generally to the formation of gate dielectrics using metal oxides, and more specifically to a method of forming amorphous metal oxide gate dielectrics.

### BACKGROUND OF THE INVENTION

Gate dielectrics are used in integrated circuits as a component of the gate structure, which controls the flow of electrical current from the source to the drain of a transistor. By reducing the thickness of the gate dielectric layer, the overall performance of the transistor is enhanced by improving the transistor's turn-on characteristics.

The trend in reducing transistor sizes has resulted in the need for an equivalent reduction in the equivalent gate dielectric thickness, where the equivalent gate dielectric thickness refers to an equivalent silicon dioxide gate dielectric thickness. One method of effectively reducing the equivalent oxide thickness in semiconductor devices has been to substitute the use of high-K dielectric materials for silicon dioxide. It is known that the physical thickness of the dielectric layer manufactured by using high-K dielectric materials can be significantly greater than an equivalent silicon dioxide dielectric layer while maintaining the same electrical properties. For example, if a silicon dioxide dielectric layer has a dielectric constant of 4, and is grown to a thickness of 30 angstroms, a high-K dielectric material having a dielectric constant of 8 would be capable of being deposited or grown to a thickness of 60 angstroms and yet have the same equivalent oxide thickness as the thinner silicon dioxide dielectric layer. Therefore, the use of high-K dielectrics is advantageous over silicon dioxide in that it allows for the processing of thicker dielectric layers, while still achieving the desired scaling to thinner equivalent oxide thickness.

Known high-K dielectric materials include metal oxides and metal silicates. Transition metal oxides, such as tantalum pentoxide, titanium dioxide, zirconium dioxide and hafnium dioxide, and the silicates of zirconium and hafnium, are known in the industry to be high-K dielectric materials with dielectric constants greater than that of silicon dioxide.

The deposition of metal oxides directly on a silicon substrate to form a polycrystalline structure has been proposed in the industry. Such a deposition would generally be performed using a PVD (Physical Vapor Deposition) or CVD (Chemical Vapor Deposition) process to form a dielectric layer of an uniform thickness from the metal oxide, while minimizing any interface materials between the silicon substrate and the deposited metal oxide. However, the formation of such a deposited metal oxide layer of this type continues to result in a thin layer of silicon dioxide forming between the silicon substrate and the deposited metal oxide gate dielectric.

The formation of silicon dioxide layer between the silicon substrate and the deposited metal oxide gate dielectric occurs due to the reactivity of the silicon substrate with any oxygen present in the ambient. As a result, the thin transition layer of silicon dioxide forms on top of the silicon substrate. The thickness of this silicon dioxide layer is generally about one nanometer thick. The presence of this thin dielectric layer forms a lower bound to the equivalent oxide thickness that can be obtained. In other words, regardless of the high-K dielectric value of the metal oxide layer, or its thickness, the achievable equivalent oxide thickness cannot drop below that of the underlying silicon dioxide interface layer.

In addition to the silicon dioxide interface layer, which limits the achievable equivalent oxide thickness, the deposition of metal oxides to form high-K polycrystalline structures has a further disadvantage of introducing trapping sites within the dielectric itself. These trapping sites, or trap sites, are capable of affecting the electrical behavior of the transistor. For example, trapping sites can affect the threshold voltage and long term reliability of a semiconductor device. Generally, these trapping sites occur between the grain boundaries of the metal oxide's polycrystalline structure.

One method in the known art to reduce the effects of the interfacial silicon dioxide layer has been to introduce a nitrogen ambient at the beginning of the formation of the metal oxide gate dielectric. By introducing a nitrogen ambient, the silicon dioxide layer will be doped with nitrogen, thereby increasing the dielectric constant. However, such a solution of introducing nitrogen results in additional processing steps and still results in a limiting oxide interface layer. In addition, presence of nitrogen at the Si/dielectric interface can increase the interface state density causing device performance degradation.

Another method in the prior art used to achieve formation of high-K gate dielectrics has been to form and dope a silicon dioxide layer with a high-K transition metal oxide. The resulting dielectric layer is lightly doped with the metal oxide such that the metal oxide to silicon oxide doping ratio is approximately 10%. However, such a solution still results in the formation of the silicon dielectric layer which has been only marginally improved by a light doping of the metal oxide. A heavier metal oxide doping in an amorphous form would be desirable in order to increase the over-all dielectric constant value. It is known in the art that the deposition of an amorphous metal oxide to form the metal oxide dielectric would result in a dielectric layer that was not susceptible to trap formation

Therefore, a method and structure capable of obtaining amorphous films with variable composition of metal oxide to silicon oxide would be advantageous.

### BRIEF DESCRIPTION OF THE DRAWINGS

FIGS. 1 and 6 illustrate one or more precursors being used to form a high-K dielectric layer on a cross-sectional view of a silicon structure;

FIGS. 2-5, and 8-9 illustrate, in formula form, precursors in accordance with the present invention;

FIG. 7 illustrates a cross sectional view of a processing chamber in accordance with the present invention; and FIG. 10 illustrates a cross sectional view of a transistor stack incorporating the dielectric of FIG. 6.

### DETAILED DESCRIPTION OF FIGURES

In accordance with a specific embodiment of the present invention, a method of forming a gate dielectric is disclosed. A semiconductor wafer is placed in a deposition chamber. The semiconductor wafer is heated and a compound such as a precursor gas is flowed into the chamber. In one embodiment, the precursor comprises a moiety of silicon, oxygen, and a transition metal. In another embodiment, the moiety includes a group 2 metal. Formation of an amorphous gate dielectric having a readily controllable metal-to-silicon ratio is realized.

The present invention is best understood with reference to the FIGS. 1-10. Specifically, FIG. 1 illustrates the semiconductor substrate 10 having a high-K dielectric layer 12 formed on top of it. In accordance with the specific embodiment of the present invention, the high-K dielectric layer 12 is an amorphous metal oxide layer. Specifically, the layer 12 can be a mixture of one or more metal oxides.

FIG. 1 illustrates an amorphous metal oxide dielectric layer 12, which has been formed through the use of multiple precursors 14 and 16. Specifically, FIG. 1 illustrates a metal oxide precursor 14 being introduced simultaneously with a silicon oxide precursor 16. By varying the concentration of the precursor 14 relative to the precursor 16, the ratio of metal oxide to silicon oxide in dielectric layer 12 can be controlled. Therefore, the dielectric constant of the high-K dielectric 12 can be varied from the dielectric value of silicon dioxide, approximately 4, to that of the dielectric value of the metal oxide being used, while forming an amorphous layer.

In a specific embodiment, a metal-to-silicon ratio of 18:7 is formed, where the ratios used herein describe the atomic ratio of transition metal atoms to silicon atoms. In other embodiments, ratios from approximately 9:1 to 1:9 are envisioned, but preferably greater than 1:1. CVD processing can be used to obtain the desired ratio by depositing at temperatures between 300° -800° C. The deposition ambient is an inert gas, such as argon, nitrogen, or an oxygen containing gas such as O₂, N₂O, or O₃. The plasma formed during the CVD process, whether remote or direct, is maintained between approximately 0-2 watts/square centimeter. The pressure used to form the dielectric layer would be maintained between approximately 0.1-100 Torr.

Examples of precursors used in accordance with the present invention include metal oxide precursors where the metal includes the group four transition metals. Examples of such precursor group four metals include titanium, tantalum, hafnium, and zirconium delivered as one of an alkoxide, a beta diketonate, and a nitrato. Specific examples include Zirconium-tertiary-butoxide, Zr(THD)4, Zr(NO3)4, and tantalum ethoxide. In addition, group 2 and group 3 metals which form silicates can be used, for example SrSiO3 and La2SiO5 respectively.

Examples of silicon precursors used in accordance with the present invention include TEOS, silane, dichlorosilane, disilane, and silicon tetrachloride.

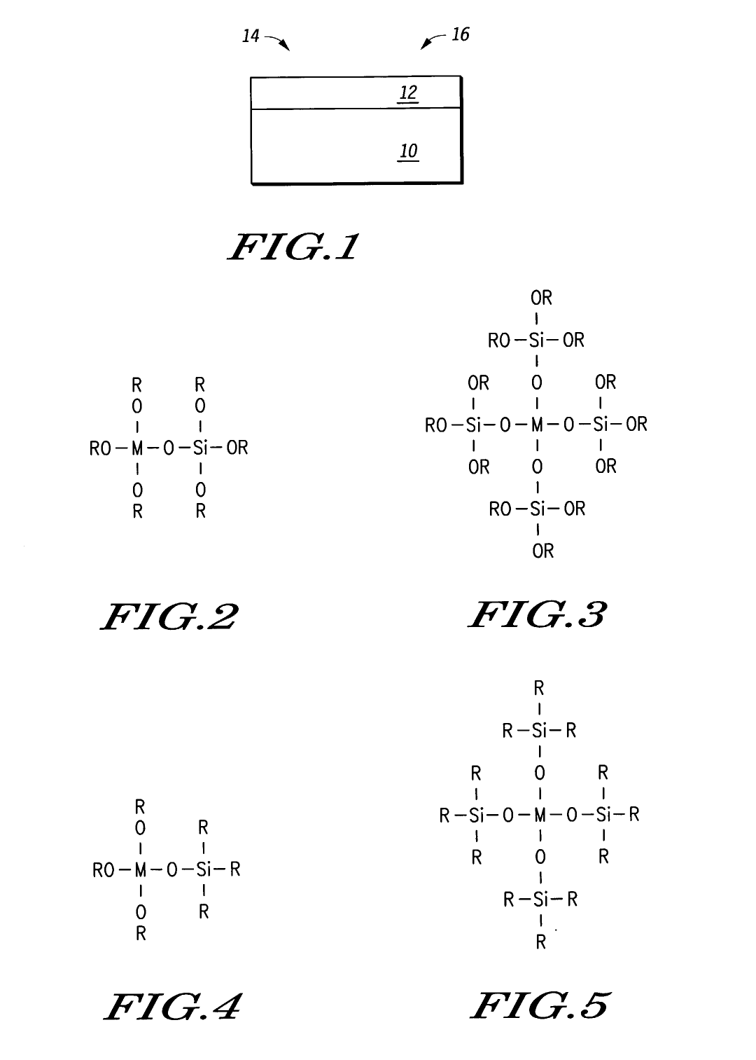

FIGS. 2 and 3 illustrate a class of precursors, which can be used as the metal oxide precursor 14 of FIG. 1. In FIGS. 2-7 the letter R represents the leaving group associated with the precursor and usually an alkyl group. The leaving group of the precursor generally is used to facilitate the transport of the moiety of the precursor. The moiety of the precursor of FIGS. 2 and 3 includes the oxygen-transition metal-oxygen-silicon portion of the precursor, where the hyphen “−” represents a bond.

In application, the precursor of FIG. 2 or FIG. 3 can be used as the precursor 14 of FIG. 1. This along with the precursor 16 results in a siliconto-oxygen bond being formed between the substrate 10 and the dielectric 12. As a result of the silicon substrate to oxygen bond, good dielectric to substrate interface properties are obtained. Furthermore, the effects of the undesirable silicon dioxide interface layer of the prior art, are reduced or eliminated, since the surface silicon bonds directly to the moiety. Therefore, the moiety of the precursor, in combination with the silicon oxide precursor 16 of FIG. 1, is allowed to control the dielectric constant of the dielectric layer 12, without being limited by the undesirable silicon dioxide interface layer of the prior art.

This is advantageous over the prior art, wherein the silicon dioxide transition layer was known to have a thickness of approximately 1 nanometer, where a pure metal oxide dielectric was deposited in polycrystalline form. In addition, an amorphous dielectric layer can be formed that consists of silicon oxide with metal oxide as dopant. The amount of metal oxide itself can be controlled by choosing appropriate process conditions such as total pressure, temperature, and partial pressures of gases.

FIGS. 4-5 illustrate another class of precursors capable of being used as the precursor 14 of FIG. 1. Specifically, the precursors of FIGS. 4 and 5 include a similar moiety as FIGS. 2 and 3, oxygen-transition metal-oxygensilicon, however, the silicon bonds of the precursors of FIGS. 4 and 5 are not bonded directly to an oxygen atom, and instead are bonded to a separate leaving group. For example, the leaving group (R) of FIG. 4 can include any alkyl. Note that the individual leaving groups of the precursors can vary within the same precursor molecule. For example, the molecule of FIG. 2 can have six different leaving groups.

The use of precursors of the type illustrated form the dielectric layer 12 as part of an abstraction reaction. Through abstraction reactions, the precursor gasses are disassociated in to radical elements, which then combine to form the substrate 12.

By controlling the concentration of the precursor 14, relative to the precursor 16, it is possible to choose a dielectric constant over a full range from approximately 4, that of silicon dioxide, to the dielectric constant of the selected metal oxide.

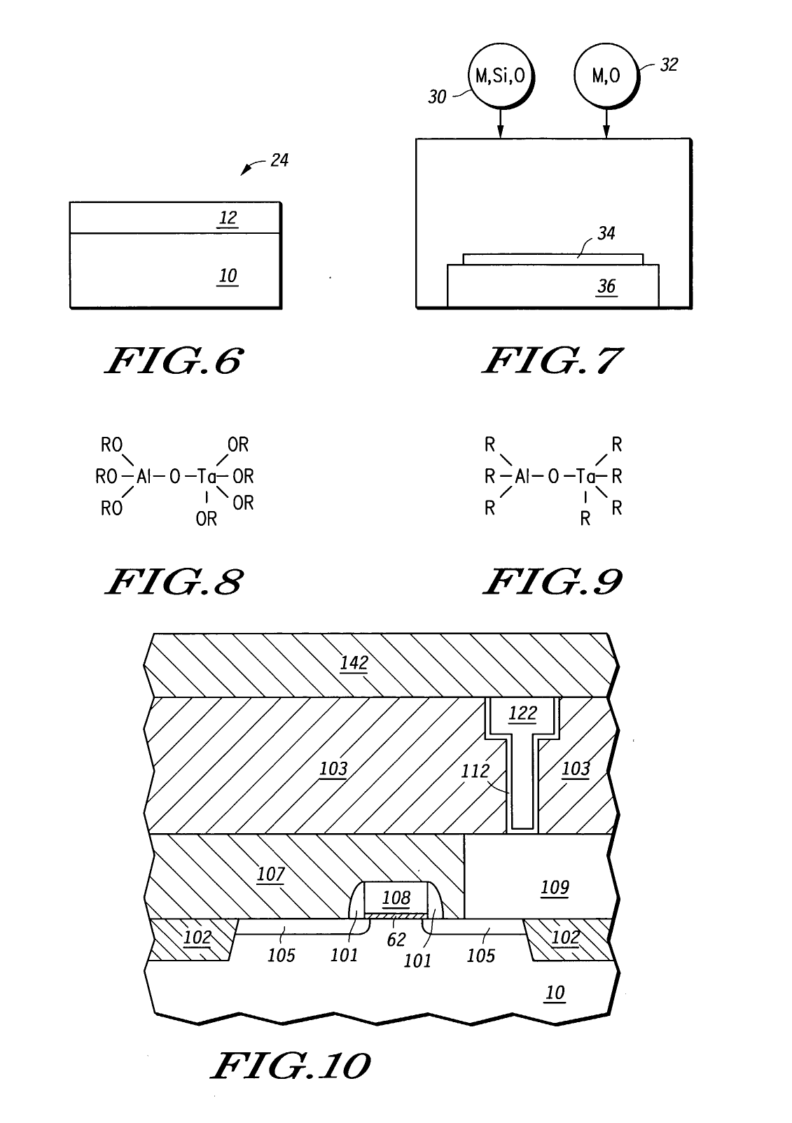

FIG. 6 illustrates another embodiment of the present invention whereby a single source of metal oxide precursor is provided to form the dielectric layer 22. Specifically, the precursors of FIGS. 2-5 can be used as a single source precursor to form an amorphous dielectric layer. Such an amorphous dielectric layer can have a fixed ratio of metal-to-silicon based upon the chosen moiety, or can have a variable metal-to-silicon ratio, which is modulated by process conditions. The advantages of using a precursor in such a method include simplicity of process, due to a single source.

FIG. 7 illustrates a processing chamber used to make the dielectric layer of the present invention. Specifically, a wafer is placed in the chamber onto semiconductor substrate holder 36. Next, the metal oxide precursor is provided from a first source 32, while the silicon precursor is provided from a second source 30. Specifically, the silicon precursor can also include a transition metal element, as discussed with reference to precursors of FIGS. 2-5, while the transition metal source 32 provides the transition metal without the presence of the silicon precursor. The temperature of the semiconductor substrate 34 is controlled by the semiconductor substrate holder 36. The semiconductor substrate holder 36 can be used to control the temperature by heating or cooling the semiconductor substrate 34.

In another embodiment, an aluminum oxide (A12O3) can be doped into metal oxides such as ZrO2, HfO2, Ta2O5, and La2O3 to form an amorphous gate dielectric. Note that all the scenarios cited above will be extendible to the A12O3 doped metal oxides and that there is a bond between aluminum and oxygen and another bond between oxygen and these transition metals. Examples of precursors including a moiety of aluminum, oxygen, and a transition metal are illustrated in FIGS. 8 and 9. FIG. 6 illustrates a semiconductor device having a gate dielectric 62 of the type described herein. Specifically, FIG. 6 illustrates transistor surrounded by isolation regions 102. The transistor includes a portion of the semiconductor substrate 10, doped regions 105, gate dielectric 62, sidewall spacers 101, and a conductive gate 108. In addition to the transistor, FIG. 6 illustrates additional layers and interconnects including a dielectric layer 107, a conductive layer 109, a dielectric layer 103, a conductive dual-inlaid structure 122 and 112, and a dielectric, or passivation layer 142. The semiconductor device as illustrated in FIG. 6 can be formed using the gate dielectric formation techniques described herein, in combination with other techniques known in the semiconductor arts to form an improved semiconductor device.

It should now be appreciated, that the device and method described herein provides advantages over the previously known devices and methods. By forming a gate dielectric using precursors of the type described, the silicon oxide transition layer associated with the prior art is reduced and or eliminated. In addition, the present method allows for a simple process flow that facilitates a readily selectable metal-to-silicon concentration. It will further be appreciated that the present invention has been disclosed it terms of specific embodiments, and that various modifications and changes can be made without departing from the scope of the present invention as set forth in the claims below. Accordingly, the specification and figures are to be regarded in an illustrative rather than a restrictive sense and all such modification are intended to be included within the scope of the present invention.

We claim:

1. A method of depositing a dielectric, comprising the steps of:
placing a semiconductor wafer in a deposition chamber; and
flowing a first compound into the chamber and onto the semiconductor wafer, wherein the compound comprises silicon, oxygen, and a metal from a group comprising zirconium, hafnium, and titanium.

2. The method of claim 1 further comprising flowing a second compound comprising the metal and oxygen.

3. The method of claim 2, further comprising heating the semiconductor wafer so that the dielectric is deposited on the semiconductor wafer and comprises a ratio of metal to silicon which is greater than one to one.

4. The method of claim 3, wherein the metal is zirconium.

5. The method of claim 4, wherein the ratio of zirconium to silicon is greater than two to one

6. The method of claim 5, wherein the ratio of zirconium to silicon is at least eighteen to seven.

7. The method of claim 3, wherein the metal is hafnium.

8. The method of claim 4, wherein the ratio of hafnium to silicon is greater than two to one

9. The method of claim 5, wherein the ratio of hafnium to silicon is at least eighteen to seven.

10. The method of claim 1, wherein the metal is zirconium or hafnium.

11. The method of claim 10, wherein the first compound further comprises one or more of alkoxy, and a Beta-diketonato.

12. The method of claim 11, wherein the dielectric is formed as a chemical vapor deposition from the first compound.

13. The method of claim 11, further comprising heating the semiconductor substrate during the flowing of the first compound.

14. A method of depositing a gate dielectric, comprising the steps of:
placing a semiconductor wafer in a deposition chamber;
heating the semiconductor wafer; and
flowing a precursor gas into the chamber and onto the semiconductor wafer, wherein the precursor comprises a moiety of silicon, oxygen, and a transition metal.

15. The method of claim 14, wherein the moiety is characterized as having a first bond between silicon and oxygen and a second bond between oxygen and the transition metal.

16. The method of claim 14, wherein gate dielectric is formed by the moiety.

17. The method of claim 14, wherein the group four transition metal is hafnium or zirconium.

18. A method of forming a dielectric comprising:
placing a semiconductor wafer in a deposition chamber;
heating the semiconductor wafer;
flowing TEOS into the deposition chamber; and
flowing a tertiary-butoxide of a group four transition metal into the deposition chamber.

19. A method of forming a dielectric comprising:
placing a semiconductor wafer in a deposition chamber;
heating the semiconductor wafer;
flowing a first gas which contains silicon into the chamber; and
flowing a second gas into the deposition chamber while the first gas is flowing, the second gas containing oxygen and a transition metal.

20. The method of claim 19, wherein the first gas is a first precursor and the second gas is a second precursor.

21. The method of claim 20, wherein the first gas flows at a rate of silicon flow and the second gas flows at a rate of metal flow, and wherein the rate of metal flow exceeds the rate of silicon flow.

22. The method of claim 21, wherein the rate of metal flow exceeds the rate of silicon flow at least by a ratio of two to one.

23. The method of claim 22, wherein the transition metal is a group four metal including one of zirconium and hafnium.

24. The method of claim 23 wherein the first gas comprises a compound of silicon, oxygen, and one of zirconium and hafnium.

25. The method of claim 23, wherein abstraction reactions of the first gas and abstraction reactions of the second gas occur to form the dielectric of a greater concentration of zirconium or hafnium than silicon.

26. A semiconductor device having a dielectric layer, the dielectric layer comprising silicon, oxygen, and a transition metal, the transition metal having a first concentration in the dielectric layer, the silicon having a second concentration in the dielectric layer, and the first concentration exceeds the second concentration.

27. The dielectric layer of claim 26, wherein the dielectric layer is amorphous.

28. The dielectric layer of claim 27, wherein the first concentration exceeds the second concentration by at least a ratio of approximately two to one.

29. The dielectric layer of claim 28, wherein the first concentration exceeds the second concentration by at least a ratio of approximately eighteen to seven.

30. The dielectric layer of claim 29, wherein the transition metal is tantalum.

31. The dielectric layer of claim 30, wherein the dielectric layer is formed by abstraction reactions of TEOS and abstraction reactions of tantalum ethoxide.

32. The dielectric layer of claim 29, wherein the transition metal is a group four transition metal.

33. The dielectric layer of claim 32, wherein the group four transition metal is hafnium or zirconium.

34. The dielectric layer of claim 27, wherein the dielectric layer is formed by chemical vapor deposition.

35. A method of forming a dielectric comprising:
placing a semiconductor wafer in a deposition chamber;
heating the semiconductor wafer;
flowing a first gas which contains silicon into the chamber; and
flowing a second gas into the deposition chamber while the first gas is flowing, the second gas containing oxygen and a group 2 metal silicate.

36. A method of depositing a gate dielectric, comprising the steps of:
placing a semiconductor wafer in a deposition chamber;
heating the semiconductor wafer; and
flowing a precursor gas into chamber and onto the semiconductor wafer, wherein the precursor comprises a moiety of aluminum, oxygen, and a transition metal

37. The method of claim 36, wherein the moiety is characterized as having a first bond between aluminum and oxygen and a second bond between oxygen and the transition metal
